(19) United States
(12) Patent Application Publication
(10) Pub. No.: US 2016/0093791 A1
(43) Pub. Date: Mar. 31, 2016

(54) APPARATUS AND METHOD FOR SEALING A MEMS DEVICE

(71) Applicant: INVENSENSE, INC., San Jose, CA (US)

(72) Inventors: Anthony D. Minervini, Palos Hills, IL (US); Brian H. Kim, Fremont, CA (US); Jia Gao, Winchester, MA (US)

(21) Appl. No.: 14/499,873

(22) Filed: Sep. 29, 2014

(51) Int. Cl. H01L 41/053; H02N 1/00

(52) U.S. Cl. CPC H01L 41/053; H02N 1/00

(57) ABSTRACT

A method and apparatus for sealing a device with a MEMS device with an active region is disclosed. A substrate with an opening is disposed relative to the MEMS device so as to align the active region of the MEMS device with the opening. A sealant is disposed between the MEMS device and the substrate so as to form a seal around the active region. The device includes one or more flow limiting features to inhibit the flow of sealant to the active region.

### RELATED APPLICATION

This application claims priority to U.S. provisional patent application 61/990,558 filed on 8 May 2014 entitled “Reliable Acoustic Sealing of Flip Chip Attached MEMS sensor”, which is incorporated herein by reference in its entirety.

### TECHNICAL FIELD

The present invention relates generally to microelectromechanical systems (MEMS) device and more particularly, to sealing one or more sensors of a MEMS device.

### DESCRIPTION OF RELATED ART

MEMS devices are formed using various semiconductor manufacturing processes. MEMS devices may have fixed and movable portions. MEMS devices may include one or more MEMS sensors. MEMS sensors may have have one or more active regions. In some examples, portions of the active region may be exposed to an external environment. In some examples, portions of the active region may be exposed to an external influence and the active region may be configured to react to the external influence. For example, a MEMS sensor may be an acoustic sensor and active region may correspond to a diaphragm of the acoustic sensor. In some examples, a MEMS sensor may be a speaker and active region may correspond to a diaphragm of the speaker that vibrates due to an applied voltage to the MEMS sensor. In yet another example, the MEMS sensor may be a pressure sensor or material sensor, with the active region configured to react to a change in the external environment. As one skilled in the art appreciates, in some examples sensor may be a transducer that changes an input received in one form to another form and based on the application, the sensor may correspond to an input device, like a microphone or an output device, like a speaker.

Sometimes, MEMS devices are packaged with other devices. For example, MEMS devices may be packaged with one or more electronic devices. These electronic devices may be disposed on a substrate. In some examples there may be a physical or mechanical connection between the MEMS device and the substrate on which other devices are disposed, in addition to electrical connection. It is beneficial to minimize any undue external influences to the active region of the MEMS sensor, apart from the selective influences the MEMS sensor is configured to react to.

With these needs in mind, the current disclosure arises. This brief summary has been provided so that the nature of the disclosure may be understood quickly. A more complete understanding of the disclosure can be obtained by reference to the following detailed description of the various embodiments thereof in connection with the attached drawings.

### SUMMARY OF THE INVENTION

In one embodiment a device with a MEMS device and a substrate is disclosed. The MEMS device includes an active region. The substrate includes an opening and is disposed relative to the MEMS device so as to expose the active region of the MEMS device through the opening. A sealant is disposed between the MEMS device and the substrate so as to form a seal around the active region, wherein the device includes at least one flow limiting feature to inhibit the flow of the sealant to the active region.

In yet another embodiment, a method for forming a device is disclosed. The method includes providing a MEMS device with an active region. A substrate is provided with an opening. The substrate is disposed relative o the MEMS device so as to align the active region of the MEMS device with the opening. A sealant is disposed relative to the MEMS device and the substrate so as to form a seal around the active region. At least one flow limiting feature is provided on the device to inhibit the flow of the sealant to the active region.

This brief summary is provided so that the nature of the disclosure may be understood quickly. A more complete understanding of the disclosure can be obtained by reference to the following detailed description of the preferred embodiments thereof in connection with the attached drawings.

### BRIEF DESCRIPTION OF THE DRAWINGS

The foregoing and other features of several embodiments are described with reference to the drawings. In the drawings, the same components have the same reference numerals. The illustrated embodiments are intended to illustrate but not limit the invention. The drawings include the following Figures:

FIG. 1 shows a device with a MEMS device and a substrate, according to one aspect of the present disclosure;

FIG. 1A shows the device of FIG. 1 with a sealant disposed between the MEMS device and the substrate, according another aspect of the present disclosure;

FIG. 2 shows the device of FIG. 1 with a plurality of flow limiting features, according to yet another aspect of the present disclosure;

FIG. 2A shows the device of FIG. 2, with a sealant disposed between the MEMS device and the substrate, according to an aspect of the present disclosure;

FIG. 2B shows the device of FIG. 2, with a sealant disposed between the MEMS device and the substrate, according to another aspect of the present disclosure;

FIG. 3 shows a top view of the substrate of device, with a flow limiting feature, according to an aspect of the present disclosure; and

FIG. 4 shows a flow diagram to seal a MEMS device to a substrate, according to one aspect of the present disclosure.

### DETAILED DESCRIPTION

To facilitate an understanding of the adaptive aspects of the present disclosure, exemplary apparatus and method for sealing a MEMS device is described. The specific construction and operation of the adaptive aspects of the apparatus and method for sealing a MEMS device of the present disclosure are described with reference to an exemplary device with a substrate.

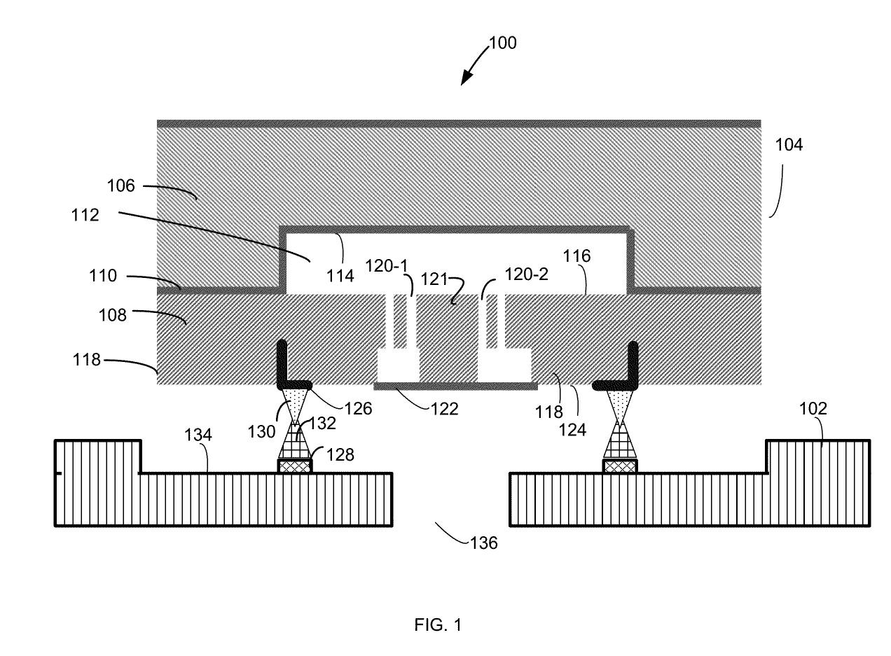

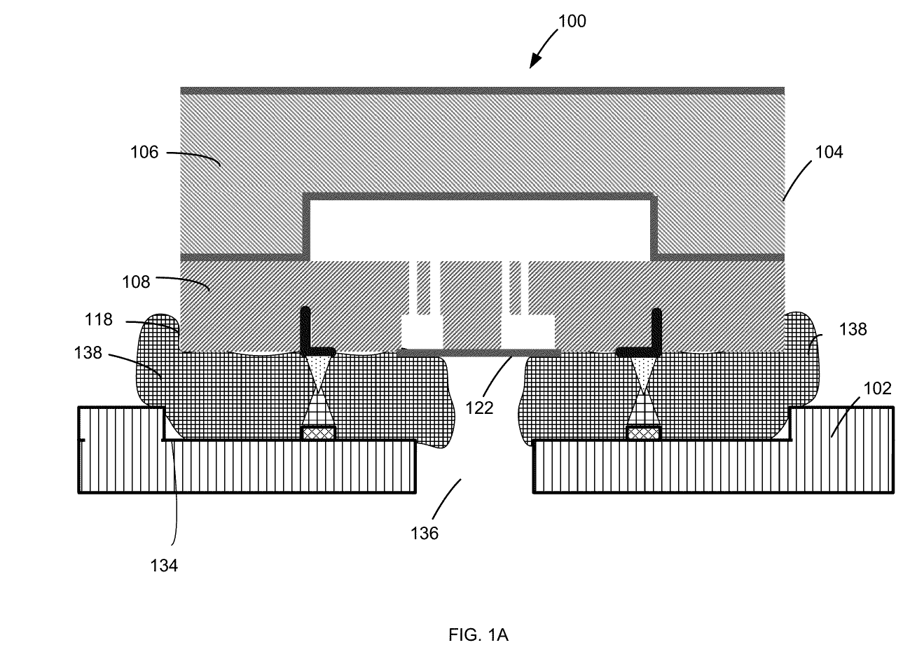

FIG. 1 shows a device 100, with a substrate 102 and a MEMS device 104. The MEMS device 104 includes a handle layer 106 and a device layer 108. One or more sensors are formed on the device layer 108. A fusion bond layer 110 bonds the handle layer 106 to device layer 108, to form an upper cavity 112, defined by the lower side 114 of the handle layer 104 and upper side 116 of the device layer 108.

FIG. 1 also shows trench patterns 120-1 and 120-2 and an actuator 121. The actuator 121 is movable and is created by forming a plurality of trench patterns 120-1 and 120-2 on the device layer 108, for example, using a DRIE process. An active region 122 is formed and coupled to the actuator 121. In some examples, the active region 122 may extend to the lower side 124 of the device layer 108. In some examples, active region 122 may correspond to a diaphragm of a speaker. In some examples, the active region may correspond to a diaphragm of an acoustic sensor. On some examples, the active region may correspond to a sensor element of a sensor.

Next, device pads 126, preferably made of aluminum alloys or germanium alloys are deposited and patterned on the device layer 108. In one example, device pads 126 may be configured to be coupled to one or more solder pads 128 disposed over substrate 102. For example, a stud bump 130 may be formed over the device pads 126 and a solder joint 132 may electrically couple the stud bump 130 to a corresponding solder pad 128 disposed over the substrate 102. One or more electronic circuits (not shown) may be disposed over the substrate 102 and the solder pad 128 may be configured to electrically couple the electronic circuit to the MEMS device.

The device layer 108 includes an edge 118. Edge 118 surrounds one or more sensors formed on the device layer 108. A sealant (not shown) is disposed around the edge 118 and extends to a top surface 134 of the substrate 102 so as to seal the active region 122 of the MEMS device 104. The substrate 102 is provided with an opening 136. The opening 136 of the substrate 102 is configured such that the active region 122 of the MEMS device 104 is exposed to the environment surrounding the substrate.

Now referring to FIG. 1A, the device 100 of FIG. 1 is shown with a sealant 138 surrounding the edge 118. As one skilled in the art appreciates, sealant 138 may be squeezed or disposed around the edge 118 in a liquid form and later cured in a curing oven. In high volume manufacturing, the device 100 is manufactured in batches and sealant 138 may be disposed in sequence on hundreds of devices in a batch and all the devices in the batch may be cured in a curing oven. In such a situation the sealant 138 is let stand in an uncured stage until sealant 138 is disposed on all the devices in the batch and plurality of devices are cured in a curing oven. In some examples, the sealant 138 may continue to flow over the top surface 134 of the substrate 102. In some examples, excessive amounts of sealant 138 may have to be disposed so as to maintain a seal surrounding the edge 118. In some examples, the sealant 138 may continue to flow and spill over through the opening 136 in the substrate 102. In some examples, the sealant 138 may continue to flow over portions of the active region 122 of the MEMS device 104 and adhere to the active region 122. As one skilled in the art appreciates, one or more of these events may be undesirable and in some examples degrade the performance of the MEMS device 104.

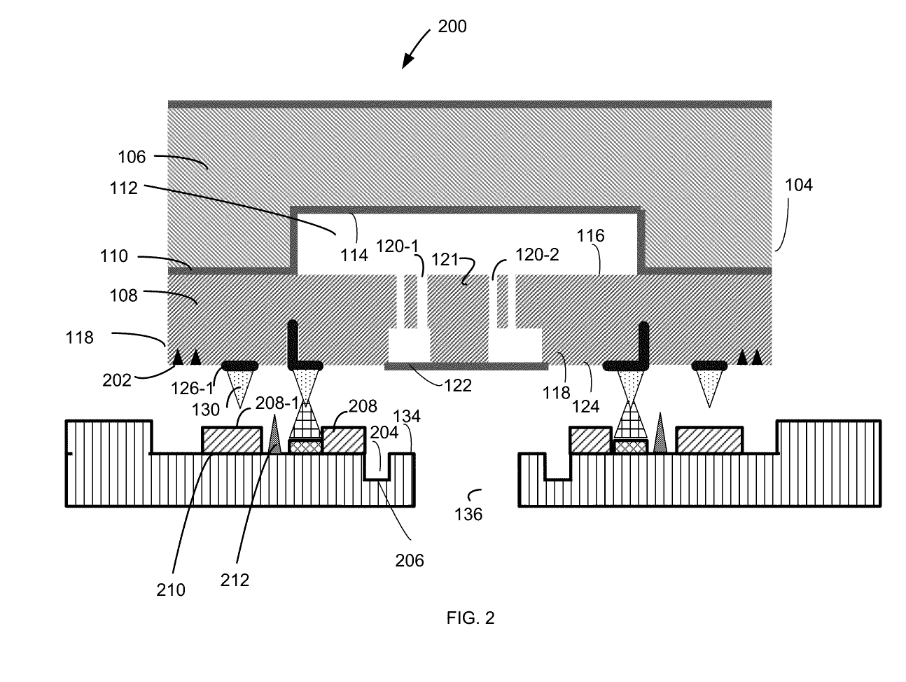

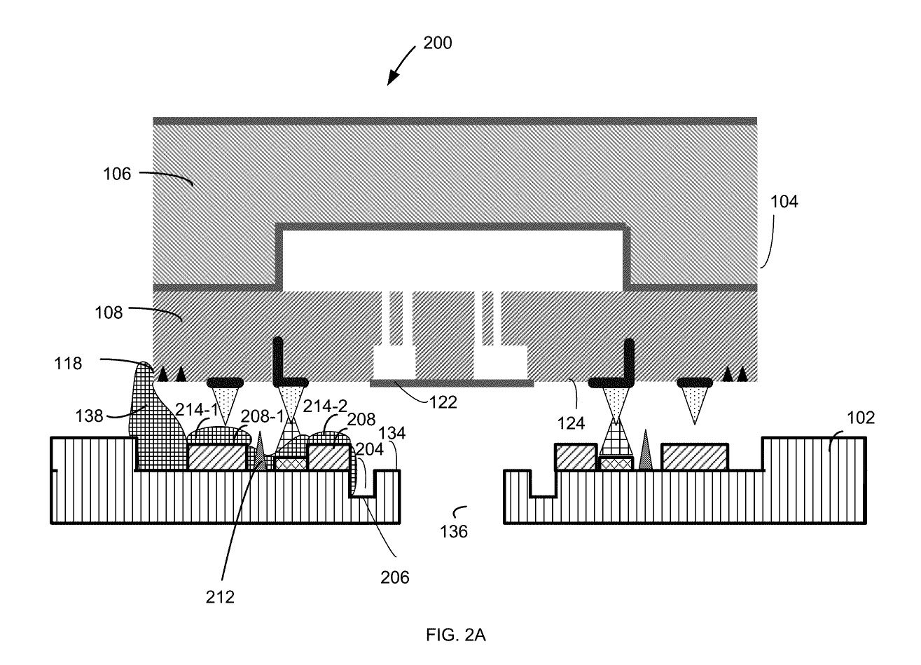

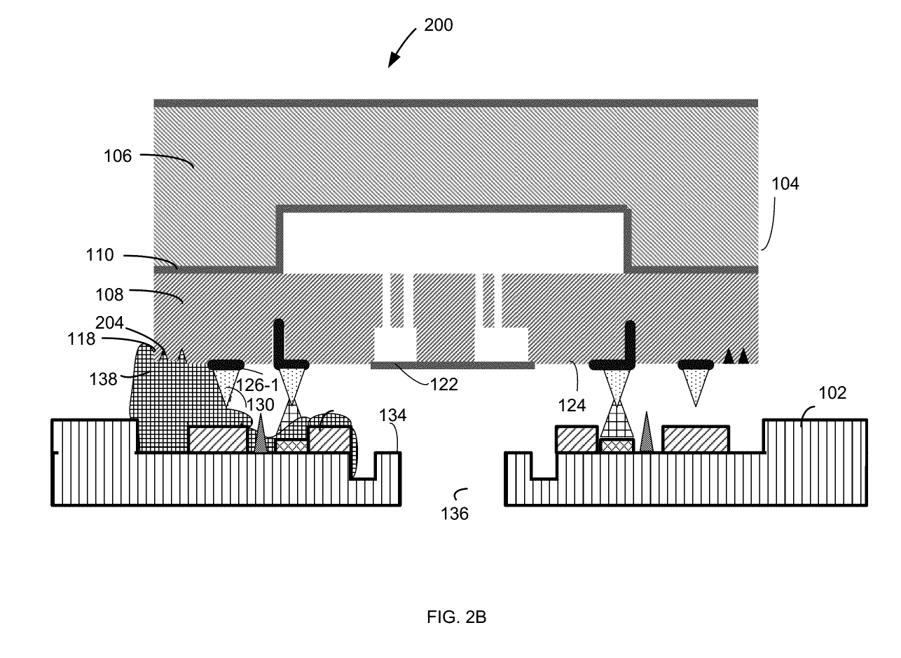

Now referring to FIG. 2, device 200 is shown with one or more flow limiting features. Device 200 may be similar to device 100 of FIG. 1, with additional features and modifications which will be described in detail now. Device 200 includes a substrate 102 and a MEMS device 104. The MEMS device 104 includes a handle layer 106 and a device layer 108.

FIG. 2 also shows trench patterns 120-1 and 120-2 and an actuator 121. The actuator 121 is movable and is created by forming a plurality of trench patterns 120-1 and 120-2 on the device layer 108, for example, using a DRIE process. An active region 122 is formed and coupled to the actuator 121. In some examples, the active region 122 may extend to the lower side 124 of the device layer 108. In some examples, active region 122 may correspond to a diaphragm of a speaker. In some examples, the active region may correspond to a diaphragm of an acoustic sensor. On some examples, the active region may correspond to a sensor element of a sensor.

Next, device pads 126, preferably made of aluminum alloys or germanium alloys are deposited and patterned on the device layer 108. In one example, device pads 126 may be configured to be coupled to one or more solder pads 128 disposed over substrate 102. For example, a stud bump 130 may be formed over the device pads 126 and a solder joint 132 may electrically couple the stud bump 130 to a corresponding solder pad 128 disposed over the substrate 102. One or more electronic circuits (not shown) may be disposed over the substrate 102 and the solder pad 128 may be configured to electrically couple the electronic circuit to the MEMS device.

The device layer 108 includes an edge 118. Edge 118 surrounds one or more sensors formed on the device layer 108. A sealant (not shown) is disposed surrounding the standoff 118-1 and extends to a top surface 134 of the substrate 102 so as to seal the active region 122 of the MEMS device 104. The substrate 102 is provided with an opening 136. The opening 136 of the substrate 102 is configured such that the active region 122 of the MEMS device 104 is exposed to the environment surrounding the substrate.

Now, some of the features and modifications of device 200 will be specifically described. More specifically, one or more flow limiting features will be described with reference to FIG. 2. In some examples, one or more device trenches 202 may be formed over the lower side 124 of the device layer 108. In some examples, the device trenches 202 may be disposed between the active region 122 and the edge 118. In some examples, the device trenches 202 may be disposed closer to the edge 118. In some examples, the device trenches 202 may be disposed closer to the active region 122. The depth of the device trenches may be such that they change a contact angle for the sealant in liquid form, when the sealant tries to flow along the lower side 124 of the device layer 108. The device trenches 202 may impede or limit the flow of the sealant.

In some examples, one or more dummy device pads 126-1 may be deposited and patterned on the device layer 108. These device pads 126-1 may not be configured to be coupled to any solder pads disposed over the substrate 102. In some examples, a stud bump 130 may be formed over the dummy device pads 126-1. In some examples, the dummy device pads 126-1 may be disposed between the active region 122 and the edge 118. In some examples, the dummy device pads 126-1 may be disposed closer to the edge 118. In some examples, the dummy device pads 126-1 may be disposed closer to the active region 122. These dummy device pads 126-1 either alone or in combination with their stud bumps 130 acts as barriers for the flow of the sealant and may impede or limit the flow of the sealants.

In some examples, one or more substrate trench 204 may be disposed on the substrate 102. The substrate trench 204 may form a trench or a reservoir, extending partially from the top surface 134 of the substrate 102 to a middle portion 206 of the substrate 102. The substrate trench 204 may be disposed in proximity to the opening 136 in the substrate 102. The depth of the substrate trench 204 may be such that they change a contact angle for the sealant in liquid form, when the sealant tries to flow along the top surface 134 of the substrate 102 and drops into the trench 204. The substrate trench 204 may impede or limit the flow of the sealant. In some examples, the substrate trench 204 may act as a reservoir to store any excess sealant that may enter the substrate trench 204 and help prevent the flow of the sealant to the opening 136 in the substrate 102.

In some examples, a selective surface 208 may be disposed over the substrate 102. The selective surface 208 may be disposed over the top surface 134 of the substrate 102. In some examples, the selective surface is disposed proximate the opening 136 in the substrate 102. In some examples, the selective surface 208 may surround the opening 136. In some examples, selective surface 208, for example, selective surface 208-1 may be disposed in an area 210 on the substrate 102 that is closer to the edge 118 and away from the opening 136. In some examples, the surface finish of the selective surface 208 may be a smoother than the surface finish of the top surface 134 of the substrate 102. In some examples, the selective surface 208 may be made of a material that is conducive to limit the flow of the sealant over the selective surface 208. In some examples, the selective surface 208 may enable the sealant to form a bead over the selective surface. In some examples, the selective surface 208 is formed as a raised selective surface over the top surface 134 of the substrate 102. In some examples, the selective surface 208 may be a solder mask. In some examples, the sealant may be composed of a compound or mixture of silicone material, a filler material and a solvent and the selective surface 208 may inhibit breaking of the sealant into its constituent parts. The selective surface 208 impedes or limits the flow of the sealants. For example, one or more of the enumerated characteristics of the selective surface either alone or in combination may impede or limit the flow of the sealant.

In some examples, one or more dummy metal bumps 212 may be disposed over the top surface 134 of the substrate 102. In some examples, the dummy metal bump 212 may be formed over a dummy solder pad (not shown) disposed over the top surface 134 of the substrate 102. In some examples, the dummy metal bumps 212 may be disposed on the top surface 134 of the substrate between the opening 136 and an area on the substrate 102 closer to the standoff 118-1. In some examples, the dummy metal bumps 212 may be disposed in an area on the substrate 102 closer to the edge 118. In some examples, the dummy metal bumps 212 may be disposed closer to the opening 136. These dummy metal bumps 212 either alone or in combination with corresponding solder pads (not shown) acts as barriers for the flow of the sealant and may impede or limit the flow of the sealants.

Now, referring to FIG. 2A and 2B, various example of operation of flow limiting features of device 200 to limit the flow of sealant 138 will be described. Referring to FIG. 2A, example operation of various flow limiting features disposed over the substrate 102 will be described.

Now, referring to FIG. 2A, sealant 138 is disposed around a periphery of the MEMS device 104 (only a portion of the sealant 138 is shown). In some examples, sealant 138 fills the gap between the lower side 124 of the device layer 108 and the top surface 134 of the substrate 102. As the sealant 138 is let stand for a while, the sealant 138 may continue to flow over the selective surface 208-1. In some examples, the selective surface 208-1 characteristics may be conducive to form a bead 214-1 of the sealant 138. In some examples, the formation of the bead 214-1 may be sufficient to prevent further flow of the sealant 138 for a considerable amount of time. In some examples, the delay in further flow of the sealant 138 may be sufficient to process the device 200 in a batch curing process. For example, the flow may be restricted for a period of time sufficient to subject the sealant 138 to a curing process.

In some examples, the sealant 138 may drop along a side of the selective surface 208-1 and continue to flow along the top surface 134 of the substrate 102. As the sealant 138 continues to flow, the dummy metal bump 212 may restrict the flow of the sealant 138. In some examples, the delay in further flow of the sealant 138 may be sufficient to process the device 200 in a batch curing process. For example, the flow may be restricted for a period of time sufficient to subject the sealant 138 to a curing process.

In some examples, the sealant 138 may continue to flow along the top surface 134 of the substrate 102 and eventually form a bead 214-2 over the selective surface 208. In some examples, the selective surface 208 characteristics may be conducive to form a bead 214-2 of the sealant 138. In some examples, the formation of the bead 214-2 may be sufficient to prevent further flow of the sealant 138 for a considerable amount of time. In some examples, the delay in further flow of the sealant 138 may be sufficient to process the device 200 in a batch curing process. For example, the flow may be restricted for a period of time sufficient to subject the sealant 138 to a curing process.

In some examples, the sealant 138 may drop along a side of the selective surface 208 and drop into the substrate trench 204. As the sealant 138 continues to flow, the sealant 138 may be held in the trench 204. As one skilled in the art appreciates, the sealant 138 has to fill the trench 204 before continuing its flow towards the opening 136. In some examples, the delay in further flow of the sealant 138 may be sufficient to process the device 200 in a batch curing process. For example, the flow may be restricted for a period of time sufficient to subject the sealant 138 to a curing process.

Now, referring to FIG. 2B, sealant 138 is disposed around a periphery of the MEMS device 104 (only a portion of the sealant 138 is shown). In some examples, sealant 138 fills the gap between the lower side 124 of the device layer 108 and the top surface 134 of the substrate 102. In this example, the sealant 138 fills the device trench 202. In some examples, the filling of the device trench 202 may be sufficient to prevent further flow of the sealant 138 for a considerable amount of time. In some examples, the delay in further flow of the sealant 138 may be sufficient to process the device 200 in a batch curing process. For example, the flow may be restricted for a period of time sufficient to subject the sealant 138 to a curing process.

As the sealant 138 is let stand for a while, the sealant 138 may continue to flow over the lower side 124 of the device layer. In some examples, the dummy device pads 126-1 and stud bump 130 disposed over the dummy device pad 126-1 may continue to restrict further flow of the sealant 138. In some examples, the delay in further flow of the sealant 138 may be sufficient to process the device 200 in a batch curing process. For example, the flow may be restricted for a period of time sufficient to subject the sealant 138 to a curing process.

As one skilled in the art appreciates, one or more flow restricting features described herein may either alone or in combination restrict the flow of the sealant 138 for sufficient amount of time to permit the curing of the sealant in a batch job, after a significant time delay. The time delay between disposing the sealant 138 to curing the sealant 138 may be of the order of about 60 minutes to about 120 minutes.

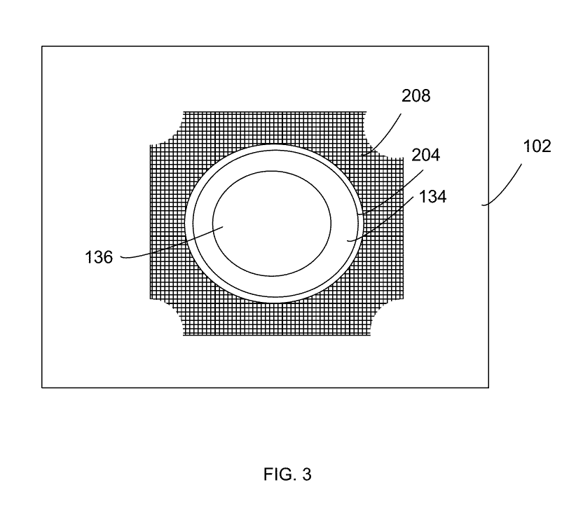

Now, referring to FIG. 3, a top view of an example substrate 102 of the device 200 is shown with opening 136. A trench 204 is formed surrounding the opening 136. A selective surface 208 is disposed around the trench 204 on the top surface 134 of the substrate 102. As one skilled in the art appreciates, FIG. 3 is showing only some of the flow limiting features described with reference to FIG. 2, 2A and 2B. In some examples, the selective surface is a solder mask that is patterned and etched around the trench 204.

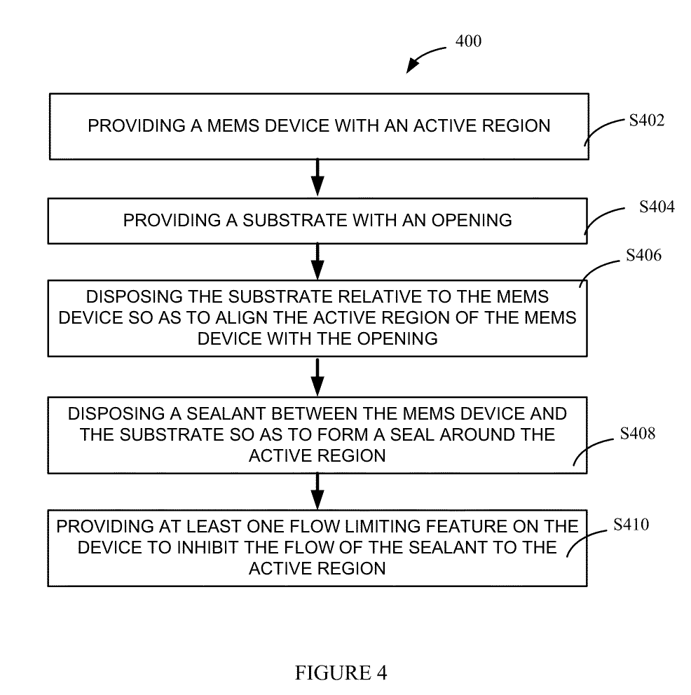

Now, referring to FIG. 4, an example flow diagram 400 will be described. In block S402, a MEMS device with an active region is provided. For example, MEMS device 104 with active region 122 is provided.

In block S404, a substrate with an opening is provided. For example, substrate 102 with opening 136 is provided, In block S406, the substrate is disposed relative to the MEMS device so as to align the active region of the MEMS device with the opening. For example, substrate 102 is disposed relative to MEMS device 104 so as to align the active region 122 with the opening 136 of the substrate 102.

In block S408, a sealant is disposed between the MEMS device and the substrate so as to form a seal around the active region. For example, sealant 138 is disposed between the MEMS device 104 and the substrate 102 so as to form a seal around the active region 122.

In block S410, at least one flow limiting feature is provided on the device to inhibit the flow of the sealant to the active region. For example, various flow limiting features are described with reference to FIGS. 2, 2A, 2B and 3. In some examples, the flow limiting feature may be a device trench 204. In some examples, the flow limiting feature may be a substrate trench 204. In some examples, the flow limiting feature may be a selective surface 208. In some examples, flow limiting feature may be a dummy pad 126-1 and a stud bump disposed over the dummy pad 126-1. In some examples, flow limiting feature may be a dummy metal bump 212.

While embodiments of the present invention are described above with respect to what is currently considered its preferred embodiments, it is to be understood that the invention is not limited to that described above. To the contrary, the invention is intended to cover various modifications and equivalent arrangements within the spirit and scope of the appended claims.

What is claimed is:

1. A device, comprising:
a MEMS device with an active region;
a substrate with an opening, the substrate disposed relative to the MEMS device so as to expose the active region of the MEMS device through the opening; and
a sealant disposed between the MEMS device and the substrate so as to form a seal around the active region, wherein the device includes at least one flow limiting feature to inhibit the flow of the sealant to the active region.

2. The device of claim 1, wherein the flow limiting feature is a selective surface disposed around the opening of the substrate wherein a surface finish of the selective surface is smooth relative to a surface finish of a surface of the substrate adjacent to the selective surface.

3. The device of claim 2, wherein the selective surface is a solder mask.

4. The device of claim 3, wherein the solder mask is formed as a raised selective surface over the substrate.

5. The device of claim 1, wherein the flow limiting feature is a device pad disposed over a surface of the MEMS device adjacent to the active region.

6. The device of claim 5, wherein a stud bump is formed over the device pad.

7. The device of claim 5, wherein a plurality of device pads are disposed over the surface of the MEMS device with a corresponding stud bump formed over the plurality of device pads, some of the stud bumps are configured to be electrically coupled to a corresponding solder pad formed on the substrate by a solder joint.

8. The device of claim 3, wherein a substrate trench is formed on the surface of the substrate, the trench formed between the solder mask and the opening in the substrate.

9. The device of claim 1, wherein the flow limiting feature is a device trench formed over a surface of the MEMS device adjacent to the active region.

10. The device of claim 1, wherein the substrate includes a raised portion, the raised portion disposed around the periphery of the MEMS device, so as to retain the sealant substantially around the periphery of the MEMS device.

11. The device of claim 1, wherein the active region is a diaphragm of a speaker.

12. The device of claim 1, wherein the active region is a diaphragm of an acoustic sensor.

13. The device of claim 1, wherein the active region is a sensor element of a sensor.

14. A method for forming a device, comprising:
providing a MEMS device with an active region;
providing a substrate with an opening;
disposing the substrate relative to the MEMS device so as to align the active region of the MEMS device with the opening;
disposing a sealant between the MEMS device and the substrate so as to form a seal around the active region; and
providing at least one flow limiting feature on the device to inhibit the flow of the sealant to the active region.

15. The method of claim 14, further including disposing a selective surface around the opening of the substrate wherein a surface finish of the selective surface is smooth relative to a surface finish of a surface of the substrate adjacent to the selective surface, the selective surface acting as a flow limiting feature.

16. The method of claim 14, wherein the selective surface is a solder mask.

17. The method of claim 16, wherein the solder mask is formed as a raised selective surface over the substrate.

18. The method of claim 14, further including disposing a device pad over a surface of the MEMS device adjacent to the active region, the device pad acting as a flow limiting feature.

19. The method of claim 18, further including forming a stud bump over the device pad.

20. The method of claim 18, further including disposing a plurality of device pads over the surface of the MEMS device with a corresponding stud bump formed over the plurality of device pads; and electrically coupling some of the stud bumps by a solder joint to a corresponding solder pad formed on the substrate.

21. The method of claim 17, further including a substrate trench formed on the surface of the substrate, the trench formed between the solder mask and the opening in the substrate.

22. The method of claim 14, further including forming a device trench over a surface of the MEMS device adjacent to the active region, the device trench over the surface of the MEMS device acting as a flow limiting feature.

23. The method of claim 14, further including disposing a raised portion over the substrate, the raised portion disposed around the periphery of the MEMS device, so as to retain the sealant substantially around the periphery of the MEMS device.

24. The method of claim 14, wherein the active region is a diaphragm of a speaker.

25. The method of claim 14, wherein the active region is a diaphragm of an acoustic sensor.

26. The method of claim 14, wherein the active region is a sensor element of a sensor.
